(19) United States
(12) Patent Application Publication
(10) Pub. No.: US 2009/0128214 A1
(43) Pub. Date: May 21, 2009

(54) DATA RECEIVER OF SEMICONDUCTOR INTEGRATED CIRCUIT

(75) Inventors: Hyung Soo Kim, Ichon (KR); Kun Woo Park, Ichon (KR); Yong Ju Kim, Ichon (KR); Hee Woong Song, Ichon (KR); Ic Su Oh, Ichon (KR); Tae Jin Hwang, Ichon (KR); Hae Rang Choi, Ichon (KR); Ji Wang Lee, Ichon (KR)

Correspondence Address: BAKER & MCKENZIE LLP;PATENT DEPARTMENT, 2001 ROSS AVENUE, SUITE 2300, DALLAS, TX, 75201, US

(73) Assignee: HYNIX SEMICONDUCTOR, INC., Ichon (KR)

(21) Appl. No.: 12/177,023

(22) Filed: Jul. 21, 2008

(30) Foreign Application Priority Data
Nov. 20, 2007 (KR) 10-2007-0118459

(51) Int. Cl. H03L 5/00

(52) U.S. Cl. 327/332; 327/306

(57) ABSTRACT

A data receiver includes a plurality of amplifiers for receiving data in response to clock signals having a predetermined phase difference, and amplifying the received data by performing an equalization function based on feedback data, thereby outputting amplification signals, and a plurality of latches for latching output of the amplifiers, respectively. One amplifier receives the amplification signal, as feedback data, from another amplifier receiving a clock signal having a phase more advanced than a phase of a clock signal received in the one amplifier.

### CROSS-REFERENCES TO RELATED APPLICATION

The present application claims priority under 35 U.S.C. 119(a) to Korean application number 10-2007-0118459, filed on Nov. 20, 2007, in the Korean Intellectual Property Office, which is incorporated by reference in its entirety as if set forth in full.

### BACKGROUND

1. Technical Field

The embodiments described herein relate to a semiconductor integrated circuit and, more particularly, to a data receiver of a semiconductor integrated circuit.

2. Related Art

As shown in FIG. 1, a 4-phase data receiver of a conventional semiconductor integrated circuit includes first to fourth amplifiers 10 to 13 and first to fourth latches 20 to 23.

The first to fourth amplifiers 10 to 13 detect and amplify data signal ‘INP’ and ‘INN’, which are input through a pad PAD and a pad bar PADB, according to clock signals ‘CLK000’, ‘CLK090’, ‘CLK180’ and ‘CLK270’ having a predetermined phase difference relative to each other.

The first to fourth latches 20 to 23 latch output data signals ‘OUT0’/‘OUTB0’, ‘OUT1/OUTB1’, ‘OUT2’/‘OUTB2’ and ‘OUT3’/‘OUTB3’ of the first to fourth amplifiers 10 to 13 according to the clock signals ‘CLK000’, ‘CLK090’, ‘CLK180’ and ‘CLK270’.

As the data transmission speed of conventional semiconductor integrated circuits becomes faster, the design margin for a data receiver for receiving high speed signal therein, is gradually reduced. One of the main factors reducing the design margin is inter-symbol interference. Inter-symbol interference is caused by an increase in signal loss as the signal frequency is increased.

Thus, the data receiving side, i.e. the data receiver, requires an equalizer that compensates for such a signal loss. The equalizer can be realized through an FFE (feed-forward equalization) scheme or a DFE (decision-feedback equalization) scheme. However, when using the FFE or DFE scheme, circuit construction may be complicated. In particular, in the case of the FFE scheme, signal noise may be amplified together with data.

### SUMMARY

A data receiver of a semiconductor integrated circuit has a simple construction as compared with a conventional circuit using an FFE or DFE scheme and is equipped with an equalizer that prevents a noise component of a data signal from being amplified.

According to one aspect, a data receiver of a semiconductor integrated circuit comprises a plurality of amplifiers for receiving a data signal in response to clock signals having a predetermined phase difference, and amplifying the received data signal by performing an equalization function based on a feedback data signal, thereby outputting amplification signals, and a plurality of latches for latching the output of the amplifiers, respectively. One amplifier receives the amplification signal, as feedback data, from another amplifier receiving a clock signal having a phase more advanced than a phase of a clock signal received in the amplifier.

According to another aspect, a data receiver of a semiconductor integrated circuit comprises a first amplifier for receiving a data signal in response to a first clock signal, and amplifying the data signal by performing an equalization function based on a fourth amplification signal serving as feedback data, thereby outputting a first amplification signal; a second amplifier for receiving a data signal in response to a second clock signal having a predetermined phase difference relative to the first clock signal, and amplifying the data signal by performing an equalization function based on the first amplification signal serving as feedback data, thereby outputting a second amplification signal, a third amplifier for receiving a data signal in response to a third clock signal having a predetermined phase difference relative to the second clock signal, and amplifying the data signal by performing an equalization function based on the second amplification signal serving as feedback data, thereby outputting a third amplification signal and a fourth amplifier for receiving a data signal in response to a fourth clock signal having a predetermined phase difference relative to the third clock signal, and amplifying the data signal by performing an equalization function based on the third amplification signal serving as feedback data, thereby outputting a fourth amplification signal.

These and other features, aspects, and embodiments are described below in the section entitled “Detailed Description.”

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIG. 1 is a block diagram illustrating a data receiver of a conventional semiconductor integrated circuit;

FIG. 2 is a block diagram illustrating a data receiver of a semiconductor integrated circuit according to one embodiment;

FIG. 3 is a circuit diagram illustrating an amplifier that can be included in the receiver of FIG. 2;

FIG. 4 is a waveform diagram illustrating the operation of the data receiver of FIG. 2; and

FIGS. 5A and 5B are waveform diagrams illustrating an operation principle of an equalization function according to one embodiment.

### DETAILED DESCRIPTION

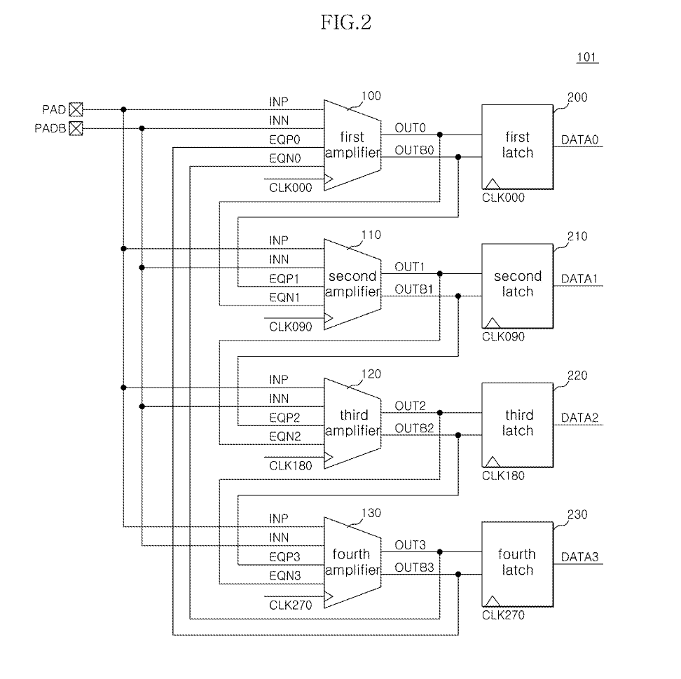

FIG. 2 is a diagram illustrating a data receiver 101 configured in accordance with one embodiment. As shown in FIG. 2, data receiver 101 can be a 4-phase data receiver and can include first to fourth amplifiers 100 to 130 and first to fourth latches 200 to 230.

The first to fourth amplifiers 100 to 130 can be configured to receive data according to first to fourth clock signals ‘CLK000’, ‘CLK090’, ‘CLK180’ and ‘CLK270’ having a predetermined phase difference relative to each other. The first to fourth amplifiers 100 to 130 can be further configured to amplify the received data by performing an equalization function based on feedback data, thereby outputting amplification signals. Each of the first to fourth amplifiers 100 to 130 can be configured to receive an amplification signal as feedback data. In the example of FIG. 2, one of the first to fourth amplifiers receives the amplification signal from another of the first to fourth amplifiers, which receives a clock signal having a phase that is more advanced than a phase of a clock signal received by the one amplifier.

The first amplifier 100 can be configured to receive differential data ‘INP’ and ‘INN’ in response to the first clock signal ‘CLK000’, and to amplify the differential data ‘INP’ and ‘INN’ by performing an equalization function based on fourth amplification signals ‘OUT2’ and ‘OUTB3’ serving as first feedback data signals ‘EQN0’ and ‘EQP0’, thereby outputting first amplification signals ‘OUT0’ and ‘OUTB0’.

The second amplifier 110 can be configured to receive the differential data ‘INP’ and ‘INN’ in response to the second clock signal ‘CLK090’, and amplify the differential data ‘INP’ and ‘INN’ by performing an equalization function based on the first amplification signals ‘OUT0’ and ‘OUTB0’ serving as second feedback data signals ‘EQN1’ and ‘EQP1’, thereby outputting second amplification signals ‘OUT1’ and ‘OUTB1’.

The third amplifier 120 can be configured to receive the differential data ‘INP’ and ‘INN’ in response to the third clock signal ‘CLK180’, and amplify the differential data ‘INP’ and ‘INN’ by performing an equalization function based on the second amplification signals ‘OUT1’ and ‘OUTB1’ serving as third feedback data signals ‘EQN2’ and ‘EQP2’, thereby outputting third amplification signals ‘OUT2’ and ‘OUTB2’.

The fourth amplifier 130 can be configured to receive the differential data ‘INP’ and ‘INN’ in response to the fourth clock signal ‘CLK270’, and amplify the differential data ‘INP’ and ‘INN’ by performing an equalization function based on the third amplification signals ‘OUT2’ and ‘OUTB2’ serving as fourth feedback data signals ‘EQN2’ and ‘EQP3’, thereby outputting fourth amplification signals ‘OUT2’ and ‘OUTB3’.

Each of the first to fourth clock signals ‘CLK000’, ‘CLK090’, ‘CLK180’ and ‘CLK270’ can have, e.g., 4-phases and a phase difference of 90°. For example, if the first clock signal ‘CLK000’ has a phase of 0°, the second to fourth clock signals ‘CLK090’, ‘CLK180’ and ‘CLK270’ can have phases of 90°, 180° and 270°, respectively.

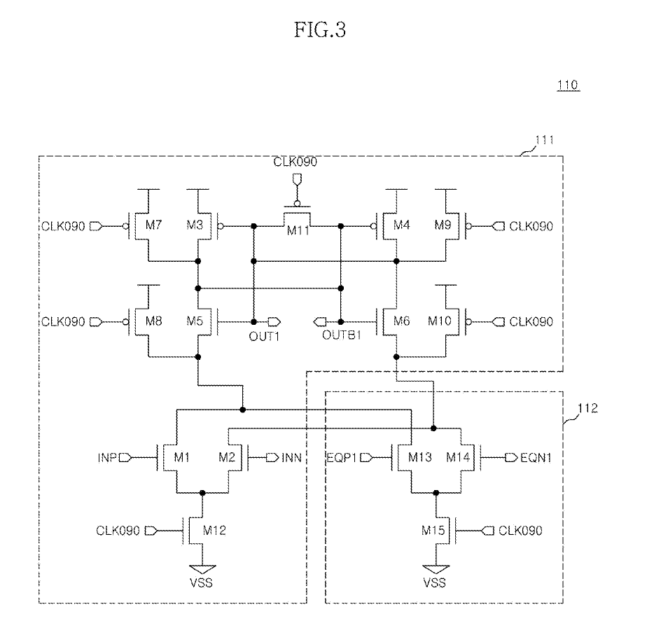

The second amplifier 110 will be representatively described with respect to FIG. 3. It should be noted that the first to fourth amplifiers 100 to 130 can have the same construction. Thus, only second amplifier 110 will be described here for ease of illustration. The second amplifier 110 can be configured to adjust an offset of a virtual reference voltage to detect the differential data ‘INP’ and ‘INN’ by using the second feedback data signals ‘EQN1’ and ‘EQP1’, thereby performing an equalization function.

As shown in FIG. 3, the second amplifier 110 can include a cross-coupled latch circuit 111 and an adjusting circuit 112. The cross-coupled latch circuit 111 can include first to twelfth transistors M1 to M12. The first to sixth transistors M1 to M6 can form a cross-coupled latch structure. The differential data signals ‘INP’ and ‘INN’ can be input to gates of the first and second transistors M1 and M2. The seventh to twelfth transistors M7 to M12 can be configured to stop the operation of the second amplifiers 110 and precharge the output terminals associated with the second amplification signals ‘OUT1’ and ‘OUTB1’ to a high level during an inactivate period of the second clock signal ‘CLK090’.

The adjusting circuit 112 can be configured to adjust the offset of the virtual reference voltage by varying turn-on levels of the first and second transistors M1 and M2 of the cross-coupled latch circuit 111, which receive the differential data signals ‘INP’ and ‘INN’ in response to the second feedback data signals ‘EQN1’ and ‘EQP1’, respectively. The virtual reference voltage is an internal voltage that serves as a reference level for determining a polarity of the difference between the differential data signals ‘INP’ and ‘INN’.

The adjusting circuit 112 can include thirteenth to fifteenth transistors M13 to M15. The thirteenth transistor M13 can have a gate, which receives the second feedback data signal ‘EQP1’, and a drain connected with a drain of the first transistor M1 of the cross-coupled latch circuit 111. The fourteenth transistor M14 can have a gate, which receives the second feedback data signal ‘EQN1’, and a drain connected with a drain of the second transistor M2 of the cross-coupled latch circuit 111. The fifteenth transistor M15 can have a gate, which receives the second clock signal ‘CLK090’, a source connected with a ground voltage terminal, and a drain commonly connected with sources of the thirteenth and fourteenth transistors M13 and M14.

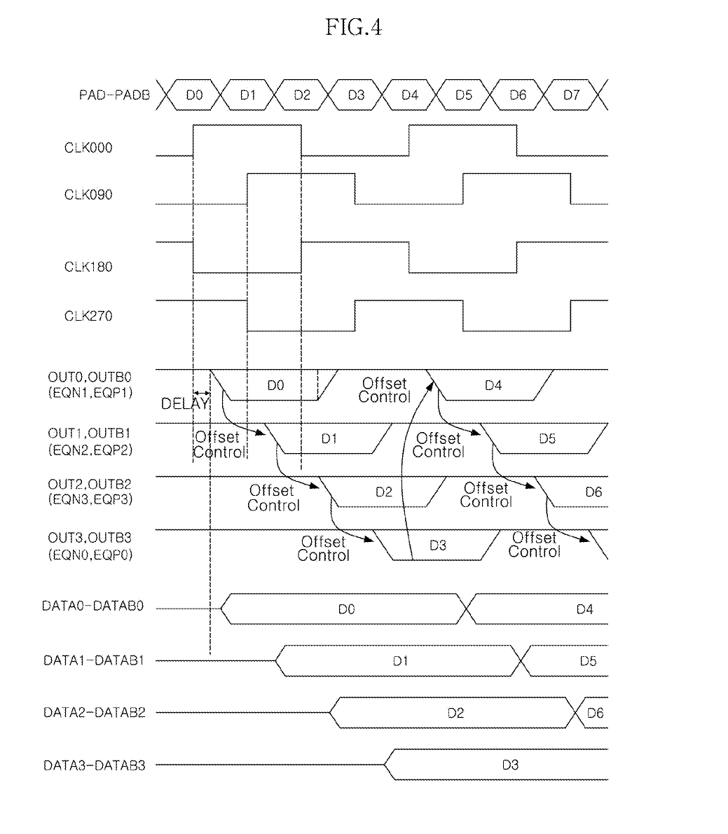

Hereinafter, an operation of the data receiver 101 will be described with reference to FIG. 4.

A plurality of data signals D0 to D7 are sequentially input through a pad PAD and a pad bar PADB. The data signals D0 to D7 can include the differential data signals ‘INP’ and ‘INN’.

The first to fourth clock signals ‘CLK000’, ‘CLK090’, ‘CLK180’ and ‘CLK270’, e.g., having a phase difference of 90° can be sequentially input to the first to fourth amplifiers 100 to 130, respectively.

The first to fourth amplifiers 100 to 130 can be configured to receive the differential data signals ‘INP’ and ‘INN’ in response to the first to fourth clock signals ‘CLK000’, ‘CLK090’, ‘CLK180’ and ‘CLK270’, respectively.

The first to fourth amplifiers 100 to 130 can be configured to detect and amplify the differential data signals ‘INP’ and ‘INN’ at rising edges of the first to fourth clock signals ‘CLK000’, ‘CLK090’, ‘CLK180’ and ‘CLK270’, thereby outputting the first to fourth amplification signals ‘OUT0’/‘OUTB0’ to ‘OUT3’/‘OUTB3’, respectively. The first to fourth amplification signals ‘OUT0’/‘OUTB0’ to ‘OUT3’/‘OUTB3’ can be sequentially used for the equalization function of the second amplifier 110, the third amplifier 120, the fourth amplifier 130 and the first amplifier 100.

The first to fourth amplifiers 100 to 130 can maintain levels of the first to fourth amplification signals ‘OUT0’/‘OUTB0’ to ‘OUT3’/‘OUTB3’ for two UIs (unit intervals), i.e. high level intervals, of the first to fourth clock signals ‘CLK000’, ‘CLK090’, ‘CLK180’ and ‘CLK270’, respectively. The period designated as (Delay), which is required for outputting the first to fourth amplification signals ‘OUT0’/‘OUTB0’ to ‘OUT3’/‘OUTB3’ at the rising edges of the first to fourth clock signals ‘CLK000’, ‘CLK090’, ‘CLK180’ and ‘CLK270’, can be smaller than one UI. However, since the first to fourth amplification signals ‘OUT0’/‘OUTB0’ to ‘OUT3’/‘OUTB3’ can be maintained for two UIs, the first to fourth amplification signals ‘OUT0’/‘OUTB0’ to ‘OUT3’/‘OUTB3’ are suitable for being used as feedback data for the equalization function.

Further, since the first to fourth amplification signals ‘OUT0’/‘OUTB0’ to ‘OUT3’/‘OUTB3’, which are amplified at a CMOS level, can be used as feedback data, noise amplification on a signal line can be prevented, or at least significantly reduced.

The UI represents a period associated with the data signals. The first to fourth clock signals ‘CLK000’, ‘CLK090’, ‘CLK180’ and ‘CLK270’ have four UIs, respectively. Thus, a phase difference of one UI, i.e. a phase difference of 90°, exists between the clock signals.

The first to fourth amplifiers 100 to 130 can be configured to detect and amplify the differential data signals ‘INP’ and ‘INN’ based on the virtual reference voltage, at which an offset is corrected, by performing the equalization function according to the first to fourth feedback data signals ‘EQN0’/‘EQP0’ to ‘EQN3’/‘EQP3’, thereby outputting the first to fourth amplification signals ‘OUT0’/‘OUTB0’ to ‘OUT3’/‘OUTB3’, respectively.

The equalization function increases the virtual reference voltage if the feedback data is at a high level, and decreases the virtual reference voltage if the feedback data is at a low level, thereby improving data detection accuracy and speed. According to the equalization function as described herein, the turn-on levels of the first and second transistors M1 and M2, which receive the data through the adjusting circuit 112 as shown in FIG. 3, are adjusted in each period of the first to fourth clock signals ‘CLK000’, ‘CLK090’, ‘CLK180’ and ‘CLK270’, so that the offset of the virtual reference voltage can be corrected.

In terms of characteristics of the amplifier, if data detection and amplification is performed by a certain degree at the rising edge of the clock signal, the amplifier can maintain the present output although an offset in the circuit is varied. Thus, although an output value is precharged at a high level as the clock signal is deactivated, output of the amplifier does not change, since it receives the feedback data generated according to a precharge interval. More specifically, the equalization function applied to an amplifier as described above uses a scheme for correcting the offset of the virtual reference voltage according to the feedback data. Since the equalization function is not affected by the feedback data generated according to the precharge interval, the equalization function can be stably performed.

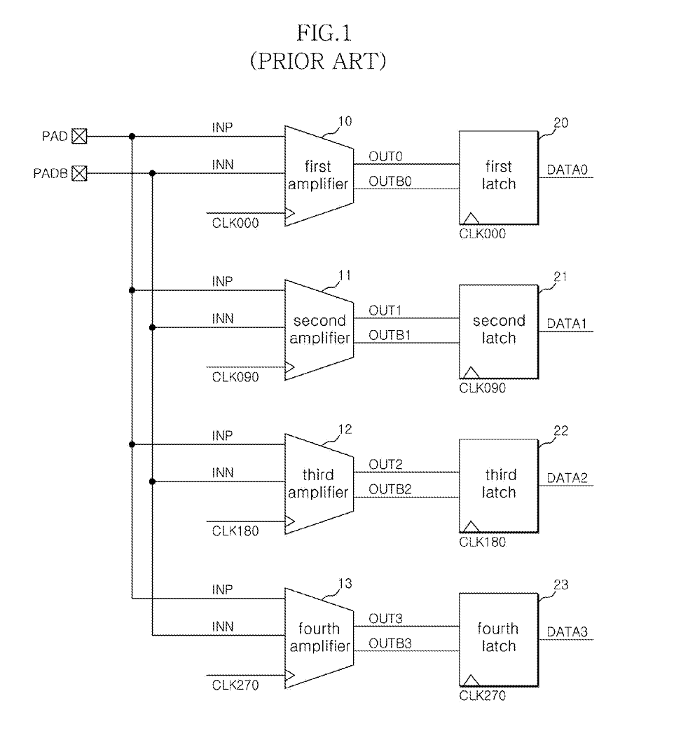

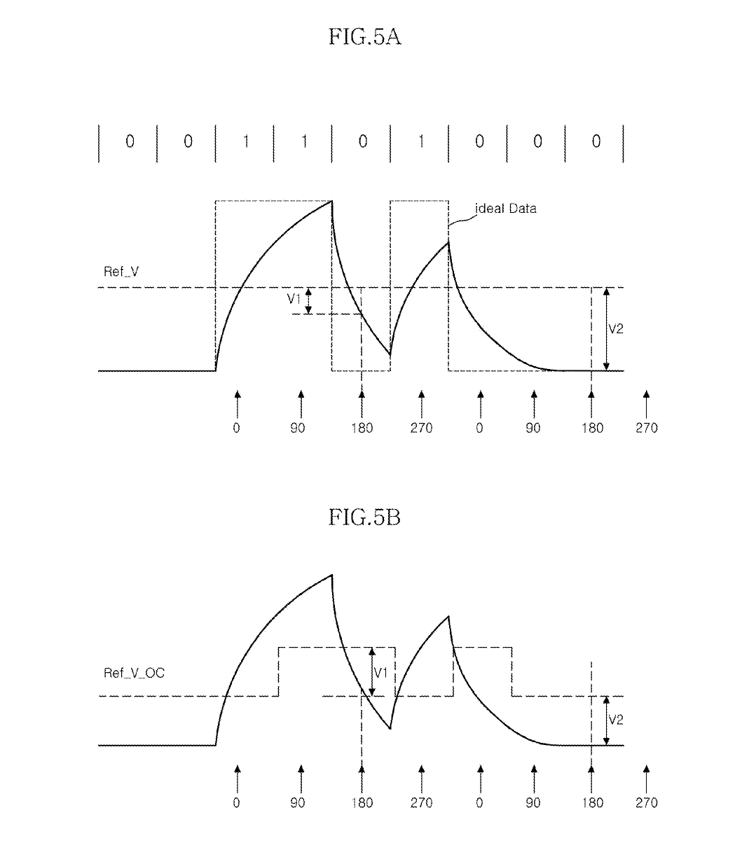

FIG. 5A is a view illustrating waveforms for explaining the operation of the amplifier in the data receiver of the semiconductor integrated circuit of FIG. 1.

In FIG. 5A, the dotted line represents ideal data. The ideal data is substantially identical to data indicated by a solid line due to attenuation of a high frequency component.

When determining the actual data indicated by the solid line based on virtual reference voltage Ref_V in the amplifier, the actual data is determined as a signal having a voltage difference V1 at a phase of 180°, and the actual data is determined as a signal having a voltage difference V2 at a subsequent phase of 180°. The V1 is smaller than V2. When V1 is very small, the amplifier may not detect V1. Further, although the amplifier may detect V1, the timing margin of a circuit for receiving the output of the data receiver is reduced due to increase in signal delay as compared with V2.

FIG. 5B is a view illustrating waveforms for explaining the operation of the amplifier in the data receiver 101.

According to the present invention, the adjusting circuit 112 detects and amplifies data according to offset correction virtual reference voltage Ref_V_OC at which the offset of the virtual reference voltage Ref_V is corrected based on the feedback data. As shown in FIG. 5B, as a level of the offset correction virtual reference voltage Ref_V_OC varies depending on a level of the feedback data, the voltage difference V1 at the phase of 180° and the voltage difference V2 at the subsequent phase of 180° are generated with a predetermined level. Consequently, data detection performance and speed at the phase of 180° can be improved.

Accordingly, an equalizer having a very simple structure as compared with an equalizer prepared through an FFE or DFE scheme can be achieved. Further, a signal amplified at a CMOS level can be used as feedback data, so that noise amplification on a signal line can be prevented. Thus, superior noise characteristics can be obtained as compared with an FFE scheme. Still further, these effects can be achieved in an equalizer that does not result in great change in the conventional data receiver, so that cost and power consumption can be reduced.

It will be apparent to those skilled in the art that various modifications and changes may be made without departing from the scope and spirit of the embodiments described herein. Therefore, it should be understood that the above embodiments are not limitative, but illustrative in all aspects. The scope of the above embodiments are defined by the appended claims rather than by the description preceding them, and therefore all changes and modifications that fall within metes and bounds of the claims, or equivalents of such metes and bounds are therefore intended to be embraced by the claims.

What is claimed is:

1. A data receiver of a semiconductor integrated circuit, the data receiver comprising:
a plurality of amplifiers configured to receive data in response to clock signals having a predetermined phase difference, and amplify the received data by performing an equalization function based on feedback data, thereby outputting amplification signals; and
a plurality of latches coupled with the plurality of amplifiers, the plurality of latches configured to latch output of the amplifiers, wherein one of the plurality of amplifiers is configured to receive the amplification signal, as feedback data, from another of the plurality of amplifiers, which receives a clock signal having a phase more advanced than a phase of a clock signal received by the one amplifier.

2. The data receiver of claim 1, wherein each of the plurality of amplifiers is configured to perform the equalization function by adjusting an offset of a reference voltage used to detect the data using the feedback data.

3. The data receiver of claim 2, wherein each amplifier includes:
a cross-coupled latch circuit configured to receive the data through a differential input terminal having first and second switching devices, and outputting the amplification signal; and
an adjusting circuit coupled with the cross-coupled latch circuit, the adjusting circuit configured to adjust turn-on levels of the first and second switching devices in response to the feedback data.

4. The data receiver of claim 3, wherein the adjusting circuit includes:
a third switching device connected with the first switching device; and
a fourth switching device connected with the second switching device.

5. The data receiver of claim 4, wherein the third and fourth switching devices are commonly connected with a ground voltage terminal.

6. A data receiver of a semiconductor integrated circuit, the data receiver comprising:
a first amplifier configured to receive data in response to a first clock signal, and amplify the data by performing an equalization function based on a fourth amplification signal serving as feedback data, thereby outputting a first amplification signal;
a second amplifier coupled with the first amplifier, the second amplifier configured to receive data in response to a second clock signal having a predetermined phase difference relative to the first clock signal, and amplify the data by performing an equalization function based on the first amplification signal serving as feedback data, thereby outputting a second amplification signal;
a third amplifier coupled with the second amplifier, the third amplifier configured to receive data in response to a third clock signal having a predetermined phase difference relative to the second clock signal, and amplify the data by performing an equalization function based on the second amplification signal serving as feedback data, thereby outputting a third amplification signal; and
a fourth amplifier coupled with the third amplifier, the fourth amplifier configured to receiving data in response to a fourth clock signal having a predetermined phase difference relative to the third clock signal, and amplify the data by performing an equalization function based on the third amplification signal serving as feedback data, thereby outputting a fourth amplification signal.

7. The data receiver of claim 6, wherein each of the first and fourth amplifiers performs the equalization function by adjusting an offset of reference voltage used to detect the data using the feedback data.

8. The data receiver of claim 7, wherein each of the first and fourth amplifiers includes:
a cross-coupled latch circuit configured to receive the data through a differential input terminal having first and second switching devices, and outputting the amplification signal; and
an adjusting circuit coupled with the cross-coupled latch circuit, the adjusting circuit configured to adjusting turn-on levels of the first and second switching devices in response to the feedback data.

9. The data receiver of claim 8, wherein the adjusting circuit includes:
a third switching device connected with the first switching device; and
a fourth switching device connected with the second switching device.

10. The data receiver of claim 6, wherein the first to fourth clock signals sequentially have a phase difference of 90°.
